(19) United States
(12) Patent Application Publication
(10) Pub. No.: US 2008/0128055 A1
(43) Pub. Date: Jun. 5, 2008

(54) Annealing-induced extensive solid-state amorphization in metallic films

(75) Inventors: Jinn P. Chu, Keelung City (TW); Chun-Hsin Kuo, Hsinchu City (TW); Chang-Ting Lo, Taipei County (TW)

Correspondence Address: BACON & THOMAS, PLLC, 625 SLATERS LANE, FOURTH FLOOR, ALEXANDRIA, VA, 22314, US

(73) Assignee: National Taiwan Ocean University, Keelung City (TW)

(21) Appl. No.: 12/068,146

(22) Filed: Feb. 4, 2008

Related U.S. Application Data
(62) Division of application No. 10/898,240, filed on Jul. 26, 2004.

(30) Foreign Application Priority Data
Aug. 4, 2003 (TW) 92121265

(51) Int. Cl. C21D 1/68; C23C 14/35

(52) U.S. Cl. 148/518; 148/537

(57) ABSTRACT

An thin film alloy based on chemical elements with high glass forming ability is disclosed. The alloy is deposited as a thin film from a source of substantially the same chemical composition. Within the deposited thin film, amorphization is induced extensively up to decades of micrometers in size during controlled annealing. Such controllable extensive amorphization throughout the thin film is useful to regulate the proportion of amorphous phase to crystalline phase, establish the structure/property relationships and thus tailor specific properties.

### CROSS-REFERENCE TO RELATED APPLICATIONS

This application is a divisional of patent application Ser. No. 10/898,240 filed Jul. 26, 2004.

### BACKGROUND OF THE INVENTION

1. Field of the Invention

The present invention relates to an alloy film and a process for manufacturing the same, especially to an annealing-induced alloy film and a process for manufacturing the same.

2. Description of the Related Art

Bulk metallic glass (BMG), also called bulk amorphous metal (BAM) or bulk amorphous alloy (BAA), is a new material with distinctive properties for special use. As compared with the traditional amorphous metals formed from melting state rapidly, this material has higher glass-forming ability (GFA). It can be made into amorphous bulk form at extremely low cooling rates and its thermal stability is better than that of the crystalline metals. For example, A. L. Greer (“Metallic Glasses”, Science, 267, 1947 (1995)), A. Inoue (“Stabilization of Metallic Supercooled Liquid and Bulk Amorphous Alloys”, Acta Mater., 48, 279 (2000)) and Y Zhang, D. Q. Ahao, M. X. Pan and W. H. Wang (“Glass Forming Properties of Zr-based Bulk Amorphous Alloys”, J. Non-crystal. Solids, 315, 206 (2003)) et al. summarized various GFA and BMG systems, such as the ternary or quaternary alloys based on Fe, Co, Ni, Pd, Zr, Ti, Mg, or La etc., or alloys with more components.

In addition to controlling the cooling rates, the supercooled liquid region (ΔT), defined by the difference between the glass transition temperature (T_{g}) and the crystallization temperature (Tₓ), can be broadened by varying alloy components so that the superplasticity in this temperature range can be utilized. Most BMG have good properties such as mechanical properties, process ability of ΔT, anti-corrosion, hydrogen-stored ability, soft magnetism and other specific optical, electrical, or chemical properties. The examples of actual commercial applications of the material include exercise apparatus and electrodes.

Crystallization generally tends to occur during thermal annealing of amorphous alloy, which is characterized by the distribution of various nano crystallites in the amorphous base and found to strengthen the alloy structures. Researches on this subject have been published by A. Inoue, C. Fan and a. Takeuchi (“High-strength Bulk Nanocrystalline alloys in a Zr-based System containing Compound and Glassy Phases”, J. Non-crystal. Solids, 250-252, 724 (1999)) and A. L. Greer et al. (“Partially or Fully Devitrified Alloys for Mechanical Properties”, Mat. Sci. Eng. A, A304-306, 68 (2001)). Different synthesis processes would influence the distribution, proportion, and routes of crystallization of the nanocrystallites. In other words, if the relationships between components, structures and properties of alloys were found, one could synthesize the materials with desired properties by proper synthesis process for specific applications.

In the solid state, amorphization could be achieved mainly by mechanical alloying, solid-state amorphization (SSA), high pressure and shock loading techniques. In all these solid-state techniques except for the SSA, considerable energy is generally required for ultimate amorphization. Metals can be also induced by hydrogen to form amorphous hydride and proceed to powder metallurgy for the solidification of BMG.

We hope that the characteristics of bulk amorphous metals can be presented in the thin film, i.e. forming a metallic glass thin film (MGTF) to extent the applications of those materials. Similar to bulk alloys, the properties of MGTF can be modified by controlling element components and nanocrystallites. The MGTF presents good properties on mechanical isotropy, structure unity, and have less crystal defects that the size effects should not be existent, and its superplasticity as bulk alloys in the supercooled liquid range is assistant to form three-dimension structures. Therefore, MGTF can be applied in various fields, especially in the fields of MEMS and optical record media.

Though the above-mentioned solid-state technique can successfully synthesize bulk amorphous alloys, it is apparent that the machining-involved technique is not suitable for films formation and the use of SSA in film formations is limited. For example, R. B. Schwarz and w. L. Johnson first proposed that the solid-state amorphization in specific multilayer structures of crystalline metals can be induced due to the annealing-induced diffusion reactions (“formation of an amorphous alloy by solid-state reaction of Pure Crystalline Metals”, Phys. Rev. Lett., 51, 415 (1983)). However, the extent of amorphization in this case is trivial and confined to the reacted interface with the thickness of few nanometers, as shown by B. X. Liu, W. S. Lai and z. J. Zhang (“Solid-State Crystal-to-Amorphous Transition in Metal-Metal Multilayers and Its Thermodynamic and atomistic Modeling” Adv. In Physics, 50, 367 (2001)).

Even various amorphous films can be formed through traditional evaporation or sputtering process, the annealing-induced crystallization reactions in both are quit different and the properties of both are not certainly identical. It is due to that the elemental components of traditional deposition and sputter systems are not necessarily the same with BMG and there are substantial differences between the film and bulk manufacturing process. For example, Y. Liu, S. Hata, K. Wada and A. Shimokohbe et al. successfully sputtered the Pd-based ternary alloy film on the aluminum layer or silicon wafer. They found that the mechanical and thermal properties of obtained MGTF are similar to those of BMG having the same components and those properties of the MGTF are influenced by the sputtering conditions. However, they didn't disclose the variance of crystallization, distribution or properties caused by heating at different temperatures. They only showed that, by way of the time-temperature-transition diagram, the MGTF have good thermal stability while compared to the crystallized, and observed that the resistance of the MGTF decreased apparently when the annealing temperature increased to Tₓ.

S. Hata, Y. Liu, T. Kato and A. Shimokohbe (“Three-dimensional Micro-Forming Process of Thin Film Metallic Glass in the Supercooled Liquid Region”, Proceeding of 10^{th} International Conference on Precision engineering (ICPE), 3741 (2001)) sputtered the Zr-based ternary alloy films and manufactured a three-dimensional cone spring by utilizing the superplasticity of such films in the supercooled liquid temperature region. According to the time-temperature-transition diagram, they simply confirmed that heating the metals with a long time in the temperature range would not result in crystallization, but they didn't disclose the variance of crystallization, distribution or properties caused by heating with different temperatures.

According to the above-mentioned prior art, a skilled person in this field could not effectively control and anticipate the structures and properties of BMG in the form of films. For example, the distribution of crystalline phase/amorphous phase could not be controlled extensively and uniformly. Thus, the requirement for thin-film alloy utilization, not bulk alloys that have thicker volumes, could not be satisfied yet.

### SUMMARY OF THE INVENTION

Accordingly, the purpose of this invention is to produce an alloy film based on elements with high glass-forming ability with extensive amorphous structures and, in the meanwhile, effectively control and anticipate its structures and properties so as to satisfy the requirements mentioned above.

In one aspect, the present invention provides an alloy film based on elements with high glass-forming ability, which is deposited as a film from a source composed of desired chemical elements, and annealed in a controllable annealing process to form partly or fully amorphous structures in the film. The alloy film of the invention includes a principal element with high glass-forming ability and at least two secondary elements different from the principal element, wherein the principal elements with high glass-forming ability are selected from a group consisting of iron, cobalt, nickel, palladium, zirconium, titanium, magnesium, and lanthanide series; the secondary elements are selected from aluminum, zirconium, copper, tin, zinc, palladium, titanium, iron, cobalt, nickel, niobium, beryllium, gallium, germanium, chromium, molybdenum, hafnium, lanthanide series, VI˜VIII group transition elements, phosphorus, boron, carbon, silicon or other metal or nonmetal elements.

In a further aspect, the present invention provides a process for manufacturing the above-mentioned alloy film, comprising the following steps: using a alloy composed of desired chemical elements as a film source, depositing the alloy onto a substrate to form a film, and annealing the film to induce partial or full amorphization in the film.

The present invention successfully induced partial or full amorphization in the films, wherein the amorphous structures distributed up to decades of micrometers and over the film extensively. Such controllable extensive amorphization in the thin film is useful to regulate the proportion of amorphous structure to crystalline structure, establish the relationships between the structure and property of the film and thus manufacture a film with specific mechanical, electrical or optical properties.

### BRIEF DESCRIPTION OF DRAWINGS

FIG. 1 shows (a) a differential scanning calorimetry (DSC) thermogram of an as-deposited Zr-based film; variations of (b) Knoop ultra-microhardness and (c) electrical resistivity with the annealing temperature. Approximate location of supercooled liquid region is marked by dash lines to facilitate visual comparison.

FIG. 2 shows the refractive index of the Zr-based films annealed at different temperatures with different light wavelengths. (a) refractive index v.s. wavelength; (b) refractive index v.s. annealing temperature at 450 nm; (c) refractive index v.s. annealing temperature at 500 nm; and (d) refractive index v.s. annealing temperature at 550 nm.

FIG. 3 shows the refractive index of the Zr-based films annealed at different temperatures with different light wavelengths. (a) refractive index v.s. annealing temperature at 600 nm; (b) refractive index v.s. annealing temperature at 650 nm; (c) refractive index v.s. annealing temperature at 700 nm; (d) refractive index v.s. annealing temperature at 750 nm.

FIG. 4 shows the refractive index of the Zr-based films annealed at different temperatures with different light wavelengths. (a) refractive index v.s. annealing temperature at 800 nm; (b) refractive index v.s. annealing temperature at 850 nm; (c) refractive index v.s. annealing temperature at 900 nm.

FIG. 5 shows plane-view transmission electron microscopy (TEM) micrographs and diffraction patterns of the Zr-based films in (a) as-deposited and annealed conditions at (b) 650 K, (c) 750 K, (d) 800 K and (e) 850 K. The circled regions in (e) indicate the locations for obtaining the diffraction patterns in (f).

FIG. 6 shows depth profiles of oxygen concentration in uncapped Zr-based films in as-deposited and 800 K-annealed conditions obtained by point analyses.

FIG. 7 shows the secondary ion mass spectrometry (SIMS) depth profile of oxygen in (a) as-deposited and (b) 800 K-annealed Zr-based films.

FIG. 8 shows a schematic illustration illustrating the free energy relationship between the metastable sputtered phase (S), amorphous phase (A), and stable crystalline phases (B and C) in the Zr-based films annealed at low temperatures and 800 K. The arrows indicate the film composition.

FIG. 9 shows electrical resistivity results of Fe-based films in as-deposited and annealed conditions. DSC result is included for comparison. Approximate location of supercooled liquid region is marked by dash lines.

FIG. 10 shows TEM micrographs of the Fe-based films in (a) as-deposited and annealed conditions at (b) 673 K, (c) 873 K and (d) 923 K.

FIG. 11 shows TEM diffraction patterns of the Fe-based films in (a) as-deposited and annealed conditions at (b) 673 K, (c) 873 K and (d) 923 K.

FIG. 12 show the variation of in-plane (a) coercivity (Hc) and (b) saturation magnetization with annealing temperatures of Fe-based films were carried out by VSM. Approximate location of supercooled liquid region is marked by dash lines.

FIG. 13 shows oxygen diffusion depth v.s. annealing temperature plot for Fe-based films as measured by SIMS.

FIG. 14 shows a schematic illustration illustrating the free energy relationship between the metastable phase (S), amorphous phase (A), and stable crystalline phases (B and C) in the Fe-based films annealed at low temperature and 923 K. The arrows indicate the film composition.

FIG. 15 shows MFM images of Fe-based films at various annealing temperatures. The black dots represent the attractive force and the white dots represent the repulsive force between the tip and sample

### DETAILED DESCRIPTION OF THE INVENTION

The details of one or more embodiments of the invention are set forth in the accompanying description below. Other features, objects, and advantages of the invention will be apparent from the detailed description, and the claims.

In one aspect, the present invention provides an alloy film based on elements with high glass-forming ability, which is deposited as a film from a source composed of desired chemical elements, and annealed in a controllable annealing process to form partly or fully amorphous structures in the film.

Generally, the usual BMG element systems are all suit for the present invention. As known by those skilled in the art, the principal element with high glass-forming ability includes iron, cobalt, nickel, palladium, zirconium, titanium, magnesium, and lanthanide series etc. Besides those principal elements, the components of the alloy film include at least two secondary elements that are different with the principal elements for assisting in amorphization and forming ternary or quaternary alloys or alloys with more components. The secondary elements include aluminum, zirconium, copper, tin, zinc, palladium, titanium, iron, cobalt, nickel, niobium, beryllium, gallium, germanium, chromium, molybdenum, hafnium, lanthanide series, VI˜VIII group transition elements, phosphorus, boron, carbon, silicon or other metal or nonmetal elements. It is apparent for one skilled person to select and determine the proportion of the above-mentioned elements. Thus the elements used in the invention are not limited to the above-mentioned.

In one preferred embodiment of the invention, the principal element with high glass-forming ability is zirconium. In this embodiment, the secondary elements with high glass-forming ability preferably include copper, aluminum and nickel. Take the Zr—Cu—Al—Ni alloy for example, the atom percentage of the alloy is zirconium 40˜60%, copper 15˜35%, aluminum 5˜20% and nickel 0˜15%; preferably, zirconium 47%, copper 31%, aluminum 13% and nickel 9%, hereafter designated as Zr₄₇Cu₃₁Al₁₃Ni₉

In the other preferred embodiment of the invention, the principal element with high glass-forming ability is iron. In this embodiment, the secondary elements with high glass-forming ability preferably include cobalt, nickel, titanium, niobium and boron. Take the Fe—Co—Ni—Ti—Nb—B alloy for example, the atom percentage of the alloy is iron 50˜70%, cobalt 5˜15%, nickel 5˜15%, titanium 5˜15%, niobium 0˜10% and boron 0˜20%; preferably, iron 65%, cobalt 8%, nickel 7%, titanium 13%, niobium 1% and boron 6%, hereafter designated as Fe₆₅Co₈Ni₇Ti₁₃Nb₁B₆.

According to the invention, partly amorphous structures are extensively formed in the film, i.e. there are extensive nanocrystallite/amorphous nanophase composite structures formed in the film. According to a preferred embodiment of the invention, for example, the Zr₄₇Cu₃₁Al₁₃Ni₉ alloy film annealed at 800 K, the amorphous structures are formed fully and extensively in the film.

In one embodiment of the invention, the thickness of the alloy film is about 0.2 μm˜50 μm. In one preferred embodiment of Zr-based alloy film, the thickness of the film is about 5 μm˜10 μm. In the other preferred embodiment of Fe-based alloy film, the thickness of the film is about 0.5 μm˜10 μm

In a further aspect, the present invention provides a process for manufacturing the above-mentioned alloy film, comprising the following steps: using a alloy composed of desired chemical elements as a film source, depositing the alloy onto a substrate to form a film, and annealing the film to extensively induce partial or full amorphization in the film.

For depositing the thin film alloy, a proper film source (or target) is prepared at first. For example, an alloy ingot with desired chemical compositions is found by the vacuum arc remelting process, and then proceed and heated into the final forms. A proper substrate for deposition is selected according to the film types and its application. The examples of substrates include well-cleaned glass, silicon or other substrates made of different materials.

The deposition process includes, for example, evaporation, sputtering, or cathodic arc, preferably the physical vapor deposition (PVD). The sputtering system used usually includes DC or RF magnetron sputtering system. In one embodiment of the invention, the working pressure and sputtering power during sputtering was maintained at 3×10⁻³ torr and 100 W respectively, and the sputtering system was in an argon atmosphere for sputtering. The deposition conditions are apparent for one skilled person in the art, thus the deposition conditions are determined in practice without limited to the above-mentioned.

The as-deposited alloy film was then annealed with suitable conditions to induce partial or extensive amorphization in the film. Due to that the behavior of crystallization in the film is influenced by the annealing conditions, the thermal behaviors of those films composed of different elements during the heating process is recorded by, for example, differential scanning calorimeter (DSC) before annealing, establishing the temperature range of supercooled liquid region and the corresponding variation of film structures, whereby determining a preferred annealing condition. The utilization of DSC results to determine annealing conditions is also known by the skilled person.

Annealing can be conducted in any anneal furnace with functions of adjusting parameters such as heating rates, temperatures, etc. According to one embodiment of the invention, the film was annealed in a rapid thermal annealing (RTA) system, such as MILA-3000 RTA system. To prevent contamination, before annealing, the annealing system was pumped down to 10⁻³ torr range followed by purging with pure argon, such as 99.9995% Ar, for several times to minimize the residual reactive gases, such as oxygen.

The heating rate of annealing is about 5 K/min˜200 K/min. In a preferred embodiment of Zr-based alloy film, the heating rate of annealing is 40 K/min. In the other preferred embodiment of Fe-based alloy film, the heating rate of annealing is 100 K/min. The temperature of annealing is preferably on the range of supercooled liquid region in order to control the reaction rate of amorphization. The supercooled liquid region varies with the components of alloys. For example, the temperature range of annealing is about 400 K˜1200 K. In a preferred embodiment of Zr-based alloy film, the temperature range of annealing is about 550 K˜950 K. In the other preferred embodiment of Fe-based alloy film, the temperature range of annealing is about 673 K˜1073 K. The holding time of annealing is about 10 s˜3600 s, preferably 60 s. The cooling rate of annealing is about 5 K/min˜200 K/min, preferably 20 K/min˜40 K/min.

### EXAMPLE 1

### Zr-Based Thin Film

### Experimental Procedure

Zr-based quaternary alloy thin films of thickness 5-10 μm with a nominal composition of Zr₄₇Cu₃₁Al₁₃Ni₉ were deposited onto the well-cleaned glass substrate using an RF magnetron sputtering system in an argon atmosphere. The working pressure and RF power during sputtering were maintained at 3×10⁻³ torr and 100 W, respectively. The compositions of the films were measured using an electron probe for microanalysis (EPMA). The compositional fluctuation at various points on the film surface was also determined and found to be very small, (around 1%) which reveals the uniformity of the deposited films. The films were then annealed in a rapid thermal annealing (RTA) system in Ar at temperatures ranging from 550 to 950 K. To avoid contamination, the RTA system was pumped down to 10⁻³ torr range followed by purging with pure Ar for several times. For RTA, the samples were kept 60 seconds in holding time with the heating rate of 40 K/min. The crystallization of the film was studied using a differential scanning calorimeter each film was delaminated entirely from the glass substrate for the DSC analysis without the aid of any chemical solutions. The crystal structures of films were examined by a transmission electron microscopy (TEM). Broad-face TEM sample discs were thinned from the substrate side by a dimpler, followed by an ion miller for the final perforation. TEM examinations were performed at 300 keV. Sheet resistance measurements of films were done at room temperature by a four-point probe method. For the mechanical property evaluation, the Knoop ultramicrohardness of film was measured. To eliminate any error due to the substrate effect, the indentation was applied with 25 g loading, 15 second holding time and loading rate of 40 μm/sec.

### Results and Discussion

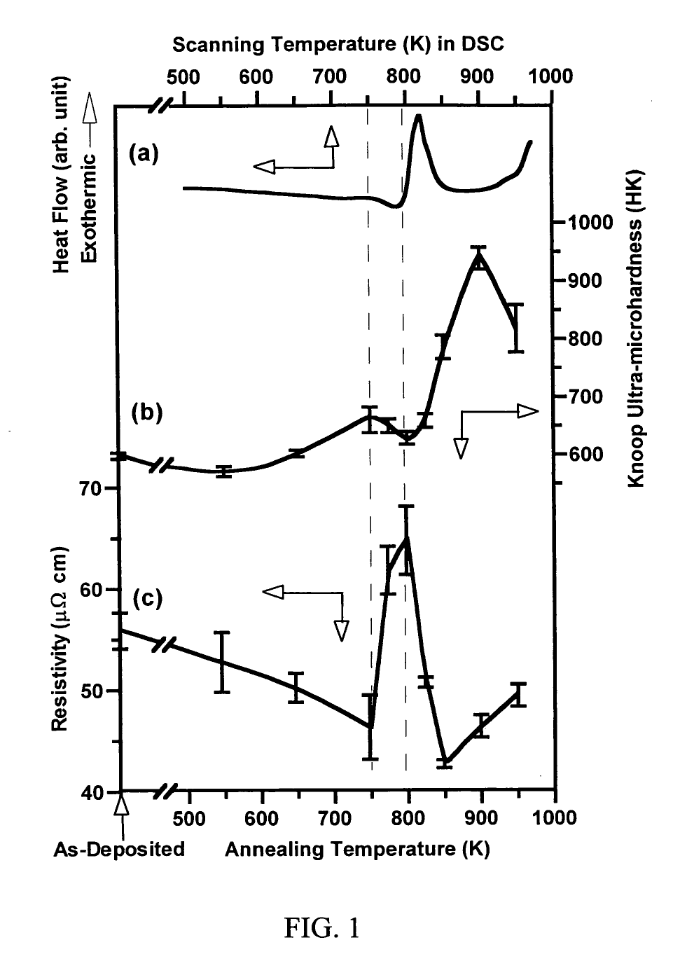

The DSC study in FIG. 1(a) reveals the as-deposited film undergoes a glass transition (Tg) and crystallization (Tx) at 758.3 K and 797.2 K, respectively. The supercooled liquid region (ΔT), conventionally defined by the difference between Tg and Tx, is thus measured to be ˜39 K. This value is comparable to 32 K reported for sputtered Pd₇₆Si₁₇Cu₇ film, but smaller than 70 K for Zr₇₅Cu₁₉Aₗ₆ film. However, the ΔT values in the thin film form are generally lower than in bulk form. AT values are 98 K and 81 K for Zr₅₅Cu₃₀Al₁₀Ni₅ and Pd₄₀Ni₄₀P₂₀ bulk metallic glasses, respectively. The differences in chemical composition and preparation methods may be attributed to the difference in ΔT. Annealing of the film at low temperatures results in the release of residual stress present in the as-deposited condition and thus causes the decrease in film hardness, as seen in FIG. 1(b). When the film is annealed below the glass transition temperature, the film hardness gradually increases with the annealing temperature and reaches a hardness value of ˜HK670 at 750 K. Such a beneficial strengthening effect is presumably attributed to the nanocrystallite/amorphous composite structure (or called nanophase composite). The film hardness then decreases slightly to ˜HK630 at 800 K for annealing temperatures within the supercooled liquid region, indicating a possible structure change in this temperature range. The hardness increases noticeably for the films annealed at temperatures above the crystallization transition, followed by a decrease in hardness due to an extensive crystallization and grain growth. With the exception of the anomalous drop in the ΔT region, the film hardness in general follows an increasing trend with annealing temperature, reaching a maximum at 900 K with a ˜60% increase from the as-deposited value. While most of other sputtered films showing a negative temperature dependence of film hardness, the films prepared in the present example revealed an increasing hardness property with annealing temperature. This distinctive behavior may be a characteristic of annealed metallic glass thin films with the nanophase composite structure, which could lead to a new class of high performance nano materials. For the electrical resistivity result in FIG. 1(c), the annealing in the ΔT region exhibits a different behavior. An abrupt increase (˜40%) in film resistivity to ˜65 μΩ-cm at 800 K is noted for the film annealed in the ΔT region. This again suggests there might be a distinct structure in the supercooled liquid region. Yet, annealing at temperatures below the glass transition results in a decrease in the film resistivity, to ˜46 μΩ-cm at 750 K. Such a decrease is originated from the combined effects of stress release, nanocrystallite growth, and reshuffling of sputtered structure, analogous to those of other sputtered metallic films. In general, a decreasing trend of the film resistivity with the annealing temperature is observed except for a dramatic increase in the supercooled liquid region. When compared with that of the sputtered Pd-based glass-forming alloy film, a similar increase in the overall decreasing trend of film resistivity near the glass transition has been reported by Liu et al. However, due to the lack of crystal structure/microstructure details and no resistivity values reported in the supercooled liquid region, it is inconclusive to determine whether full amorphization in their films is obtained in the supercooled liquid region.

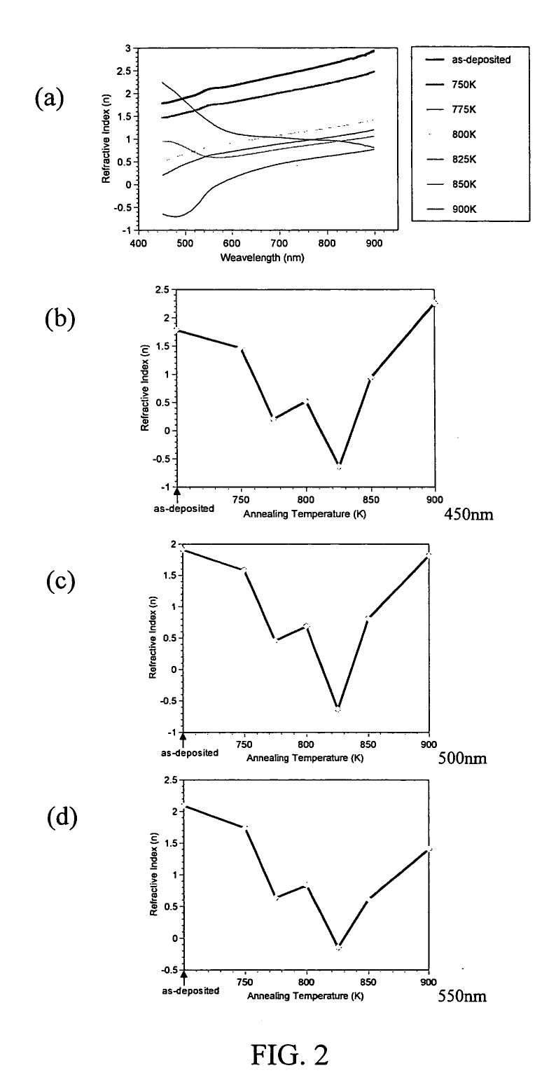

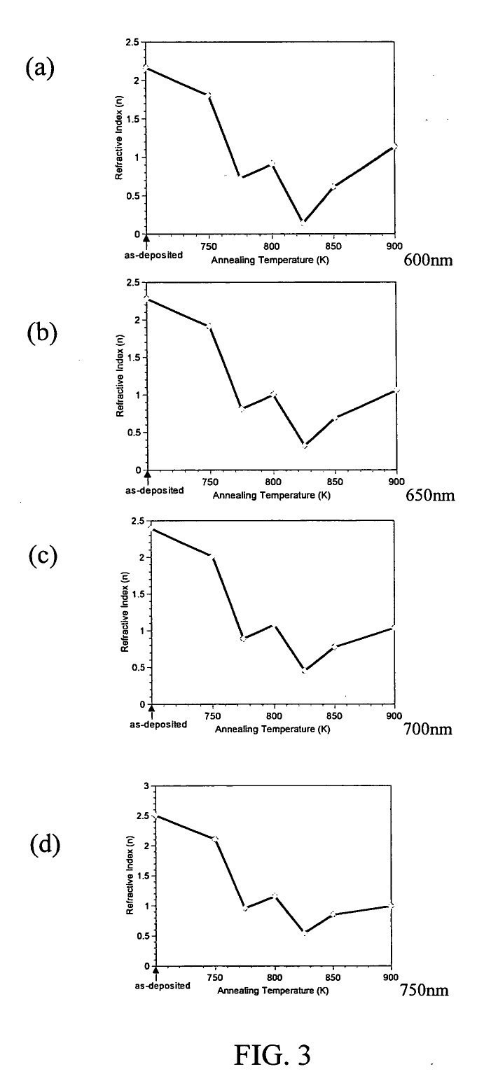

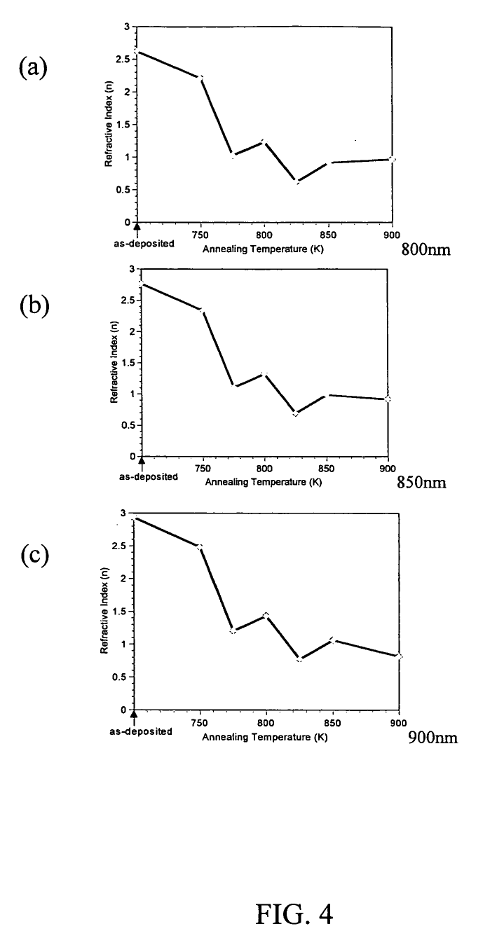

Except varying with temperature and light wavelengths, the refractive index varies with elemental components of the material. The refractive indexes of the films annealed at different temperatures v.s. light wavelengths are show in FIGS. 2, 3 and 4. When the film is annealed at temperatures below the glass transition temperature, such as a temperature below 750 K, the film refractive index decreases for all given wavelengths. Such phenomenon is presumably attributed to the nanophase composite. The film refractive index then slightly increases about 0.2 with annealing temperatures in the supercooled liquid region, such as 750˜800 K, indicating that the film structure changed in this temperature range. The film refractive index decreases again when the annealing temperature increased over the crystallization temperature, such as over than 800K, due to the occurrence of crystallization. For example, the minimum refractive index occurs at 825 K. Then with temperatures increasing again, the crystal growth is more remarkable and the refractive index increases, while the increasing range and the given wavelength shows an inverse relationship. For example, the film refractive index for short wavelength light may increase back to that of as-deposited film, but the increase of refractive index for long wavelength light is unapparent. Briefly, except for the supercooled liquid region, the film refractive index substantially decreases with increasing temperatures, but it changes with light wavelength when annealed at a temperature above the crystallization temperature.

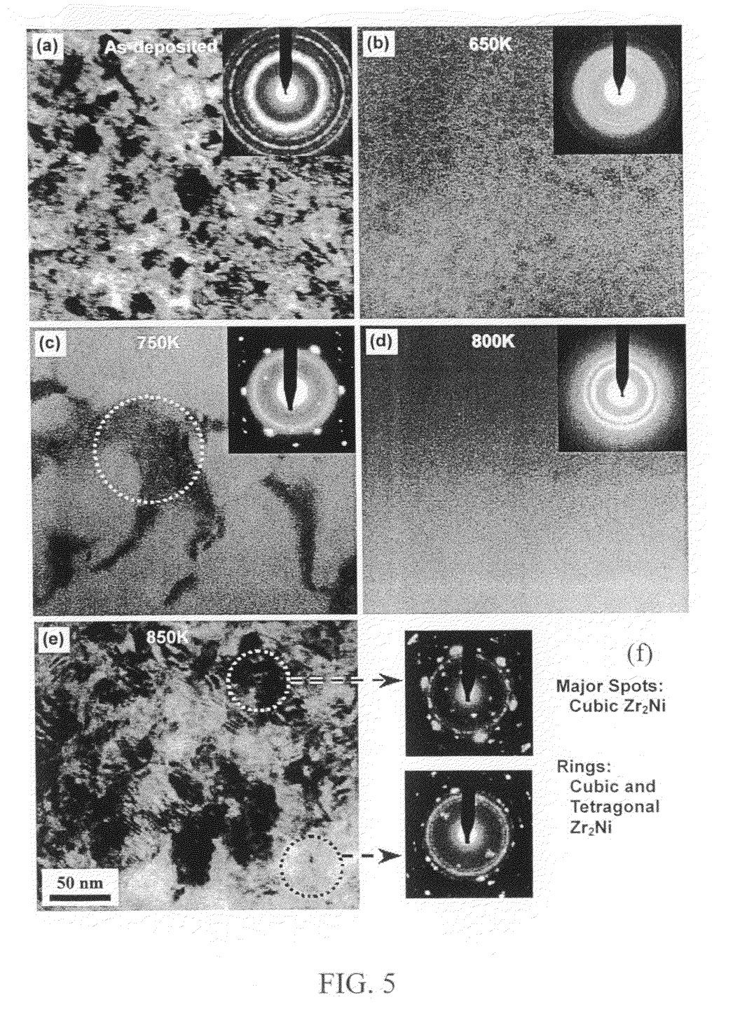

FIG. 5 represents the TEM results of the films in the as-deposited and annealed conditions. The TEM image in FIG. 5 (a) and a typical corresponding diffraction pattern indicate the dominant structure in the as-deposited condition is the nanocrystalline structure and the amorphous is found to be a minor phase. The nanocrystallites have sizes in a range of 10-30 nm and thus produce a spotty-like ring diffraction pattern as shown in FIG. 5(a). Measurements performed on the diffraction pattern show that the structure is either tetragonal Zr₂Ni (JCPDS 38-1170) or cubic Zr₂Ni (JCPDS 41-0898). After annealing at 650 K, the thermal-activated stress release and reshuffling of sputtered structure promote better amorphization and refined crystallites, developing a glassy (amorphous) matrix containing uniformly dispersed nanocrystalline phases, as indicated in the TEM image in FIG. 5(b). The refined crystallites reveal sizes in the range between ˜10 and 20 nm. The well-defined, continuous ring diffraction pattern in FIG. 5(b) suggests the film consists of the rather fine nanocrystalline structure than that in the as-deposited condition. When annealed at 750 K, about the onset of the glass transition, the agglomeration and growth of nanocrystalline phases in the form of crystalline networks embedded in the amorphous matrix are seen in FIG. 5(c). More crystalline spots in the diffraction pattern of FIG. 5(c) indicate these phases are better crystallized. The crystal structure, however, could not be unambiguously identified.

Annealing at 800 K, in the ΔT region, produces a fully amorphous structure without any observable crystalline phases, as evidenced by the TEM image of FIG. 5(d) and by the typical broad diffuse diffraction rings characteristic of a glass in FIG. 5(d). The presence of this distinct amorphous structure thus explains anomalous properties observed in the ΔT region in FIGS. 1(b) and (c). For the 850 K-annealed films, above the crystallization transition, the crystalline phases increase in distribution and grow in size compared to the sample annealed at 750 K (FIG. 5(e)) as a result of devitrification. The crystallinity of the glassy matrix also improved considerably as evidenced by the spotted rings in the diffraction pattern in FIG. 5(e). The crystalline phases could not be definitely identified; but they are likely to be Zr₂Ni. After annealing at 950 K, well above the crystallization transition, the film develops a homogenous structure consisting of a uniformly dispersed large crystalline phase in a nanocrystalline matrix (FIG. 5(e)). The structure of the large crystalline phase is the same as that observed in the sample annealed at 850 K. Annealing at temperatures well above the crystallization transition results in an extensive growth of crystallites, thus deteriorating the film hardness and resistivity properties shown in FIGS. 1 (b) and (c).

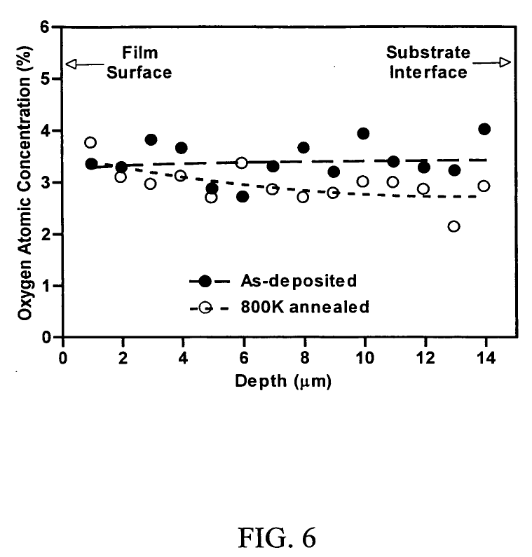

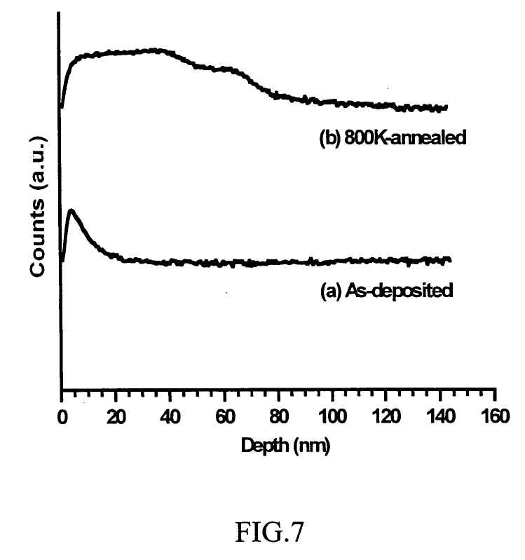

We now discuss the mechanism by which the partly amorphous film dispersed with crystallites is transformed to the fully glassy state during annealing. Since impurities such as hydrogen have been reported to induce amorphization in many alloys under highly pressurized (˜5 MPa) and thermal environment, species in the substrate and residual gases in the RTA system might have possibly played roles to promote the amorphization in our case. However, such possibilities are not likely because the short annealing duration (60 seconds) and relatively low operational pressure are unfavorable to allow the diffusion-driven reactions to occur. Furthermore, oxygen impurity and contamination are known to strongly affect the stability of the amorphous phase in BMG. As Zr and its alloys are known to be susceptible to oxidation, incorporation of oxygen into the film is often very difficult to avoid even in the reduced and protective annealing environment. However, the oxygen effect would be negligible for the annealing temperatures ≦800 K on account of the following reasons. Interaction of Zr with oxygen involves both oxygen dissolution and formation of scale (mainly ZrO₂). The scale formation was limited in this study because our X-ray diffraction analysis results (which are not shown here) revealed the presence of oxide phases only at and above 850 K. The oxygen dissolution during annealing is thus considered in this study. In the absence of an exact diffusion coefficient, D, we take an Arrhenius expression, D(in cm²/sec)=5.2exp[−212/(8.314*T)], where T is absolute temperature. This expression has been commonly used for Zr and its alloys to determine the depth of oxygen dissolved into the metal through volume diffusion. Based on X=2\sqrt{Dt}, where t is the annealing time and X the distance at which the oxygen concentration falls to half the initial value of maximum solubility (28.5%) at the metal oxide interface, and an assumption that the time spent in heating up to 0.8 of annealing temperature makes insignificant contributions to the total amount of diffusion, depths of oxygen dissolution into our annealed films are estimated to be 0.1, 0.3, 0.7, 1.4 μm for 800, 850, 900 and 950 K, respectively. The estimate is consistent with the depth profile of oxygen concentration shown in FIG. 6. This figure indicates no oxygen contamination due to annealing at 800 K. The average oxygen content in the as-deposited film is, within the experimental error, nearly equal to that of the sample annealed at 800 K. The oxygen content of the Zr-based film is performed by secondary ion mass spectrometry (SIMS), as shown in FIG. 7. The depth profile of oxygen shows that the oxygen dissolution in the as-deposited film is 20 nm, while in the 800K-annealed film is 80 nm. 80 nm in depth is considered to be insignificant for the whole film thickness of 10 μm. Based on FIGS. 6 and 7, we conclude that the formation of amorphous phase during the 800 K annealing is not associated with oxygen contamination at all. Furthermore, no apparent thickness dependence of amorphization for the 5-10 μm film thickness range examined suggests the negligible effect of this diffusion-driven event.

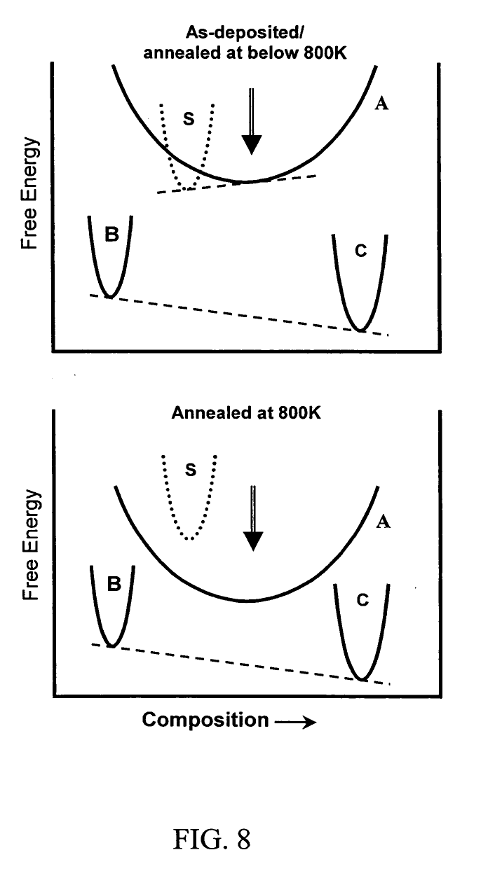

To interpret the present results and explain the thermodynamics that govern the structure evolution during annealing, hypothetical free-energy diagrams are shown in FIG. 8. The diagrams, though approximate, contain the essential features required to interpret the present results. The relative position of the free energy curves in the figure is rationalized based on thermodynamic considerations. In this figure, of primary importance is the large negative heat of mixing observed for the Zr-based alloy system. Inoue has suggested that the large negative heat of mixing enables multicomponent alloys to readily form a glassy phase during cooling from the melt. The large negative heat of mixing and hence the low free energy for the amorphous phase can be related to the amorphization in our case. The low free energy serves as the thermodynamic driving force for the amorphous phase to form as an intermediate phase during annealing, which eventually becomes thermodynamically stable by full crystallization at high temperatures. Based on the schematic, it is anticipated that similar amorphization behavior could take place in other sputtered glass-forming films with large negative heat formation.

It has been proposed that sufficient thermal-driven diffusions and high interfacial energies between two different phases are prerequisite for the SSA to take place. Our result-thus demonstrates, as we qualitatively hypothesized, the thermal energy supplied by the annealing and the interfacial energy arising from the nanocrystallite/glass interfaces might have imparted significant influences on the amorphization and crystallization of film during annealing. Upon annealing at below the supercooled liquid region, the interfacial energy appears to be predominant because of the presence of nanocrystallites, and hence the growth of nanocrystalline phases is favorable. In addition, the viscosity of glass matrix presumably decreases with the annealing temperature, analogous to that required for the superplasticity behavior of metallic glasses. The glassy matrix with sufficiently low viscosity thus allows the nanocrystalline phases to “move around” in the matrix. Ultimately, nanocrystallites become interconnected and form a network structure. Once this interconnected crystalline network structure is formed, facilitating the flow of electrical current, a decrease in resistivity is thus expected (FIG. 1(c)). The thermal energy in this case, however, is insufficient due to the low annealing temperatures and subsequently the amorphization occurs with limited extents, in spite of the relatively high interfacial energy. Yet, the extent of amorphization increases resulting from sufficient thermal-driven diffusions for the high annealing temperatures. Eventually, for the full amorphization at 800 K, as-sputtered nanocrystallites are thermally annihilated and “liquefied” into the glassy matrix, on account of the combined effects of sufficient thermal energy and excessive interfacial energies. Contrary to the planar interfacial area in SSA multilayer films, our irregular and plentiful nanocrystallite/glass interfaces that are present throughout the film are considered to yield much higher interfacial energies. This, in turn, leads to the possibility of the occurrence of large-scale amorphization in our film. While the extensive amorphization reported in this study is beneficial for ease of characterizations and readiness for potential applications, evaluations of additional properties (such as optical) and searching for other possible glass-forming systems exhibiting this phenomenon will be the subjects of further work. Moreover, the controllable amorphous structure may serve as a precursor for a new class of nano materials.

In summary, here we show direct experimental evidences that annealing of Zr₄₇Cu₃₁Al₁₃Ni₉ film at a temperature within the supercooled liquid region results in extensive amorphization, presumably attributed to sufficient thermal and interfacial energies between nanocrystallites and glassy matrix. The formation of comprehensive amorphous structure gives rise to notable alterations in the electrical and mechanical properties of annealed film. Additional features of the present work are that a prominent strengthening effect is observed due to the improved amorphous matrix dispersed with nanocrystalline phases upon annealing and that one can take this advantage to tailor the film properties by modulating the amorphous content in the annealed films. The controllable amorphization may also serve as a precursor for exciting new nano materials.

The details of above-mentioned Zr-based alloy film have been published on Physical Review B, Vol. 69, page 113410 in March of 2004.

### EXAMPLE 2

### Fe-Based Thin Films

### Experimental Procedure

The Fe₆₅CO₈Ni₇Ti₁₃Nb₁B₆ (atomic percent, at. %) thin films were prepared by an RF magnetron sputtering method. The Fe—Co—Ni—Ti—Nb—B target was an as-cast alloy. Thin films of thickness 0.5-10 μm were deposited on glass substrate. The deposition was carried out under the following conditions. The base vacuum was 10⁻⁷ Torr, Ar gas flow rate was 20 sccm, and the working pressure was 3×10⁻³ Torr. The power of 100 W was applied during the deposition. The film was annealed in Ar at a heating rate of 100 K/min and a holding time of 60 s at temperatures ranging from 673 to 1073 K. The annealing system was pumped down to the 10⁻³ Torr range followed by several purging with Ar. Compositions of thin films were determined by Electron Probe Microanalyzer. The thermal behavior of the film was determined using a differential scanning calorimeter (DSC) in Ar at a scanning rate of 100 K/min. The DSC film sample was delaminated from the glass without the aid of any chemical solutions. Sheet resistance and hardness measurements were carried out by four-point probe and Knoop ultramicrohardness methods, respectively. The ultramicrohardness was measured with a 25 g loading, a 15 holding time, and a loading rate of 40 μm/s. The crystal structures of films were examined by a transmission electron microscopy (TEM). TEM examinations were performed at 200 keV. The composition distribution and oxygen content of the films were performed by secondary ion mass spectrometry (SIMS, Cameca IMS6F), depth-profiling studies were carried out by Ar sputtering. The coercive field (Hc) and the saturation magnetization were measured at room temperature by a vibrating sample magnetometer (VSM), using maximum field strength of 7500 Oe.

### Results and Discussion

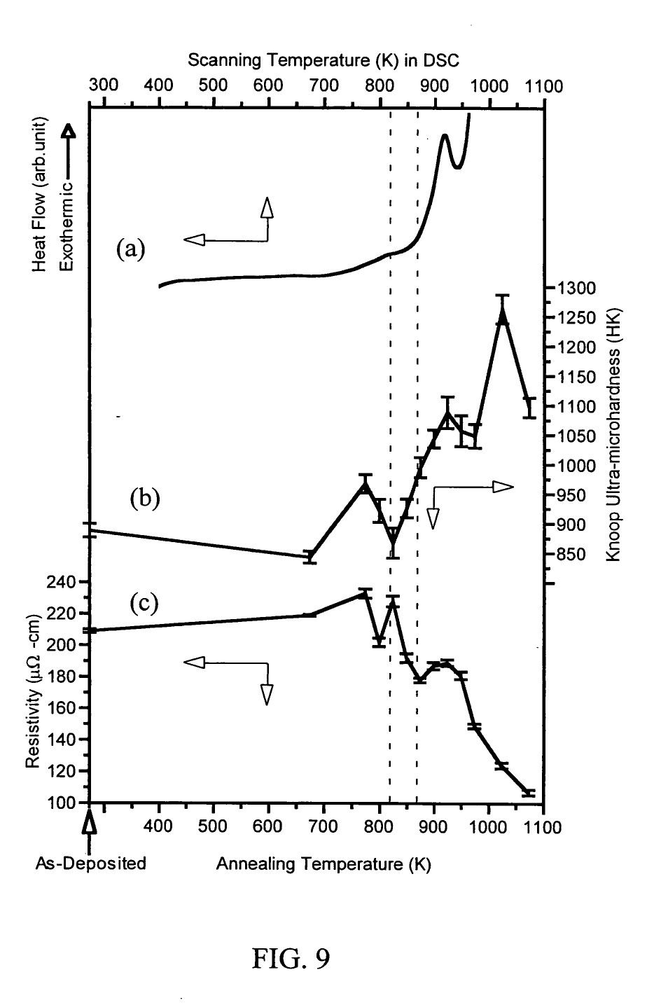

FIG. 9 (a) shows the DSC scan of as-deposited thin film at scan rate of 100 K/min. From FIG. 9 (a), the Fe-based thin film metallic glass exhibits a slope change due to glass transition at about 816 K and exothermic reactions due to crystallization at about 866 K and 950 K. Thus, its glass transition temperature (T_{g}), crystallization temperature (Tₓ) are 816 K and 866 K, respectively. The supercooled liquid region (ΔT), defined as the difference between T_{g} and Tₓ, is thus measured to be ˜50 K. When compared this value with the reported for Fe—Co—Ni—Ti—Nb—B and Fe—Al—Ga—P—C—B alloys, our ΔT value was smaller than those studies, even though there were differences in the apparatus and heating rate conditions between this work and those studies. Based on the DSC results, the annealing temperatures of the films were determined. The DSC results also reveal the heat of exothermic reaction (ΔH) of thin film from the area under exothermic peaks. The two exothermic peaks are considered be caused by the nucleation (the first peak) and by the growth of nuclei (the second peak), as proposed in other amorphous thin films. Table 1 lists summary results of DSC for as-deposited film at scan rate of 100 K/min.

TABLE 1

| | | Glass | Crystallization Temperature | | | |
|---|---|---|---|---|---|---|
| | | Transition | (K) | | | |
| | Scan Rate | Temperature | Onset | Peak | ΔH | ΔT |
| | (K/min) | (K) | (K) | (K) | (J/g) | (K) |
| Fe-based | 100 | 816 | 866 | 913 | 765 | 50 |
| thin film | | | | | | |

Thermal annealing results in variations of microstructure/crystal structure in the film and thus film properties such as hardness and electrical resistivity have been altered. Annealing of the Fe-based films at low temperatures yields the release in the residual stress present in the as-deposited condition and thus causes the decrease in film hardness, as seen in FIG. 9 (b). When the films are annealed at temperatures below the glass transition, the film hardness gradually increases with the annealing temperature, reaching ˜HK967 at 773 K. Such beneficial strengthening effect is presumably attributed to the nanocrystallite/amorphous composite structure (or called nanophase composite). Similar hardness variation of film due to this nanophase composite has been also reported in the previous example of the Zr-based film during annealing. The film hardness decreases slightly to ˜HK867 at 823 K, and ˜HK1048 at 973 K, indicating a possible structure change in this temperature range. The hardness increases for the films annealed at temperatures above the crystallization transition, followed by a decrease in hardness, as a result of extensive crystallization and grain growth. With exception of the anomalous drop in the ΔT region, the film hardness in general follows an increasing trend with annealing temperature, reaching a maximum at 1023 K with a ˜42% increase from the as-deposited value. While most of other sputtered films showing a negative temperature dependence of film hardness, the film prepared in the present study has a hardness property increased with annealing temperature. When compared with that of the sputtered Zr-based glass-forming alloy film, the Fe-based film in the present study reveals similar increasing trend of hardness variation with annealing temperature except for the two decreases at 823 K and 973 K. The distinctive behavior of positive temperature dependence of hardness may be a characteristic of annealed glass-forming thin films with the nanophase composite structure, which could lead to a new class of high performance materials.

FIG. 9 (c) shows the electrical resistivity results of Fe-based films in as-deposited and annealed conditions. From this figure, the annealing in the ΔT region causes different behavior. It is noted an abrupt increase in film resistivity to ˜255 μΩ-cm at 848 K, then decreased to ˜233 μΩ-cm at 873 K for the film annealed in the ΔT region. This again agrees with the distinct structure change in the supercooled liquid region. Yet, annealing at temperatures below the glass transition results in an abrupt decrease in the film resistivity to ˜224 μΩ-cm at 773 K, then slightly increased to ˜228 μΩ-cm at 798 K. Such a transition is originated from the combined effects of stress release, nanocrystallite growth, and reshuffling of sputtered structure, analogous to those of other sputtered metallic films. In general, a decreasing trend of our film resistivity with the annealing temperature is observed except for a dramatic transition in the supercooled liquid region.

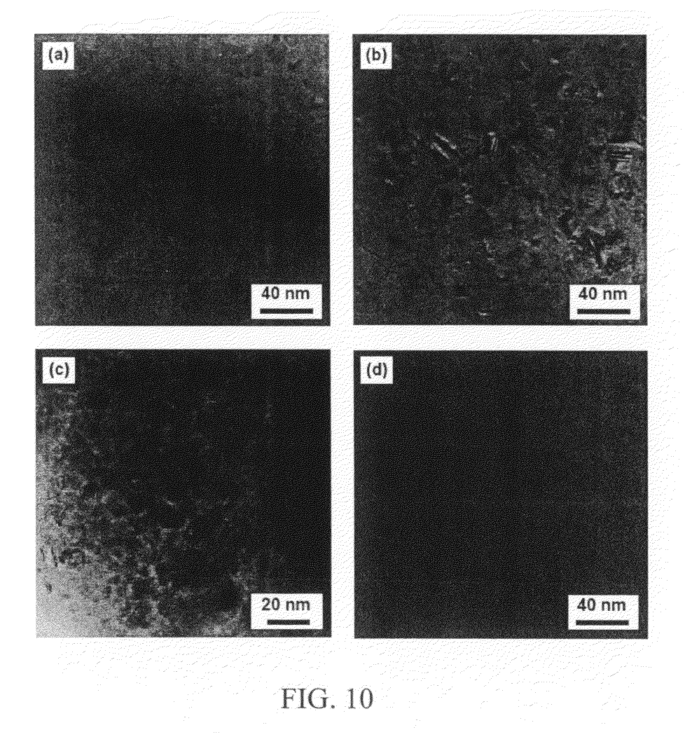

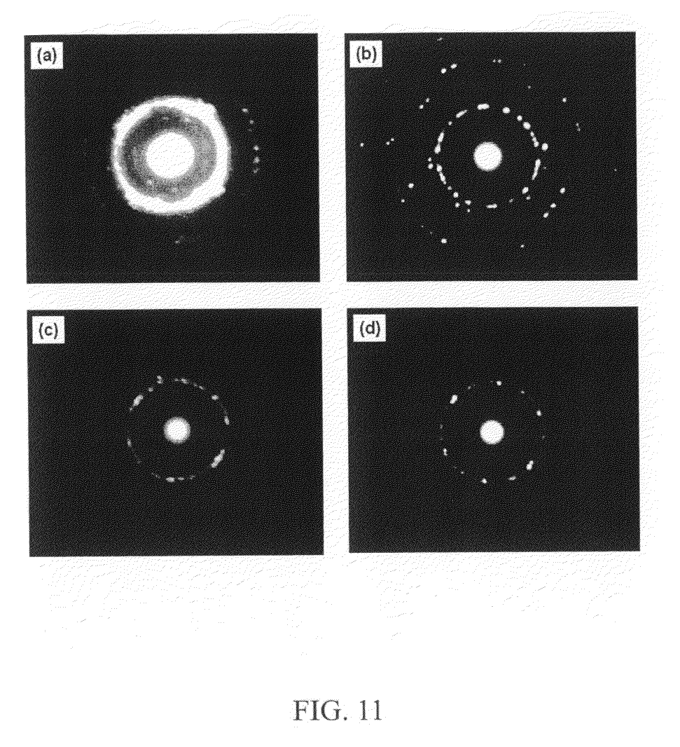

FIGS. 10 and 11 show TEM bright-field images and corresponding diffraction patterns, respectively, of Fe-based films in as-deposited and annealed conditions. The as-deposited film exhibits nanocrystalline peaks dispersed in an amorphous matrix. The sizes of nanocrystalline phases range from 2 nm to 5 nm. According to the d-spacing measured from the diffraction pattern (FIG. 11 (b)), the nanocrystalline are likely to be cubic FeNi (JCPD#18-0645). The annealing at 673 K for 60 s yields better crystallinity and growth of nanocrystalline phases with amorphous structure becoming indistinct. These are evidenced by twinned grains in TEM images (FIG. 10 (b)) and well defined spotty rings in diffraction patterns (FIG. 11 (b)). Based on FIG. 11 (b), the d-spacing of diffraction rings are 2.048 \acute{Å}, 1.79 \acute{Å}, 1.27 \acute{Å}, 1.08 \acute{Å} and 0.81 \acute{Å}, respectively. The sizes of the nanocrystalline are in a range of 5 to 9 nm. The diffused spotty rings in diffraction patterns (FIG. 11 (c)), and poorly defined crystalline phases in the amorphous matrix (FIG. 10 (c)) at 873 K indicate that the nanocrystalline phases appear to dissolve in the amorphous matrix and lose their crystallinity. With 50 K increase in annealing temperature to 923 K, the film reveals more amorphous structure in the matrix with less nanocrystalline phase. The TEM results shown here are somehow consistent with those reported earlier in Zr-based glass-forming films.

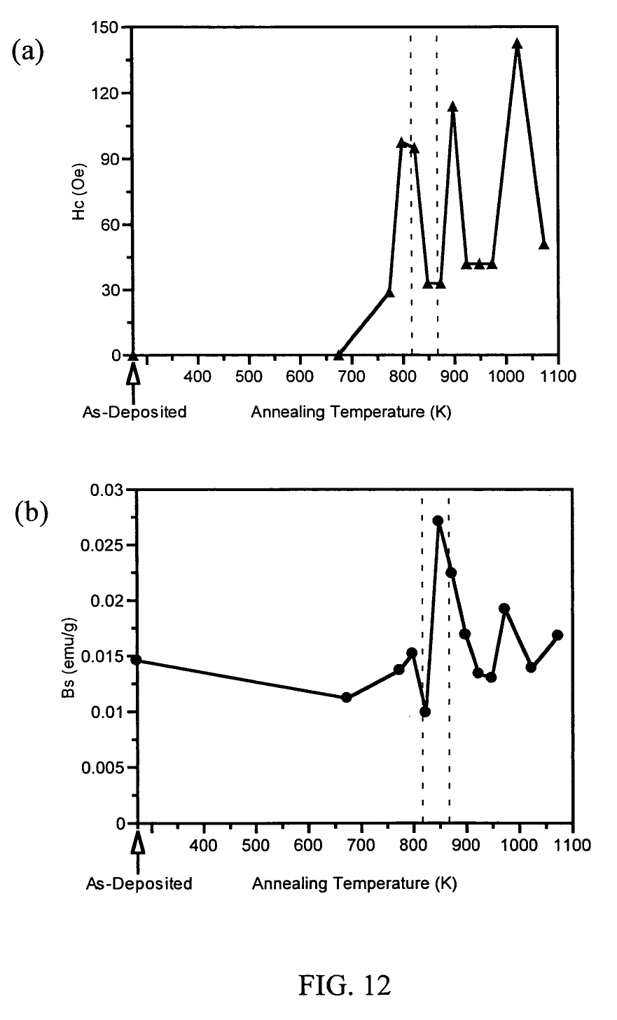

FIG. 12 (a) shows the variation of in-plane coercivity (Hc) and saturation magnetization with various Fe-based films in as-deposited and annealed conditions. As shown in FIG. 12 (a), when the films are annealed at temperatures below the glass transition, the coercivity increases with the annealing temperature, reaching 97.5 Oe at 798 K. The film coercivity gradually decreased to 33 Oe at 873 K for annealing temperatures within the supercooled liquid region, and then the film coercivity increased to 114 Oe at 898 K. The coercivity gradually decreased for the films annealed at temperatures above the crystallization transition, followed by a significant increase in coercivity, which corresponds to extensive crystallization and grain growth. Thus, cyclic variations of coercivity and saturated magnetization with annealing temperature are observed. A detailed analysis is needed in order to understand such cyclic behavior of magnetic properties. From FIG. 12 (b), we also find the cyclic behavior of saturated magnetization. The saturated magnetization slightly decreased to 0.0112 emu/g at 673 K. When the annealed condition at 798 K, the saturated magnetization increased to 0.0152 emu/g. The minimum saturated magnetization was 0.0099 emu/g at 823 K, and the maximum saturated magnetization was 0.0271 emu/g at 848 K, for annealing temperatures within the supercooled liquid region. The saturated magnetization gradually dropped to 0.013 emu/g at 948 K, and then up to 0.0192 emu/g at 5 973 K for annealing temperature above crystallization temperature. Based on FIGS. 12 (a) and (b), we found that the low coercivity (˜330e) and maximum saturated magnetization (˜0.0271 emu/g) within supercooled liquid region. Further studies on such cyclic behavior at different annealing temperatures are needed in order to establish better understanding on the magnetic of this film.

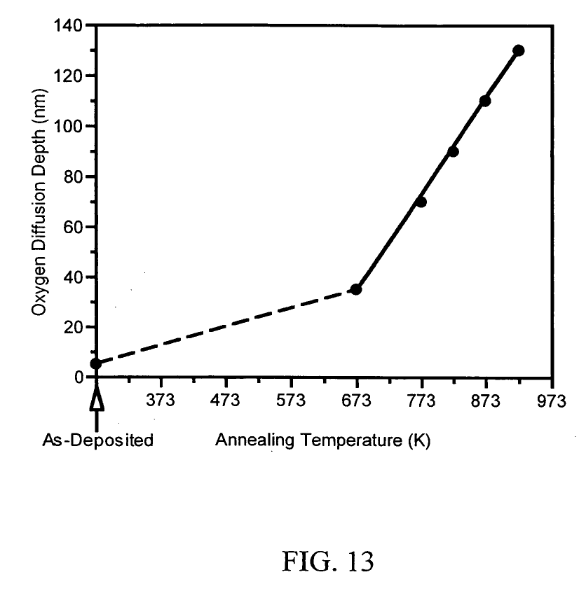

Since impurities such as hydrogen have been reported to induce amorphization in many alloys as mentioned in the previous example of Zr-based film, FIG. 13 is the oxygen diffusion depth of the Fe-based film v.s. annealing temperature plot, as measured by SIMS. According to this figure, the oxygen diffusion depth up to 130 nm is insignificant when compared with the whole film thickness of 10 μm. Thus, it is concluded that the oxygen impurity effect is negligible.

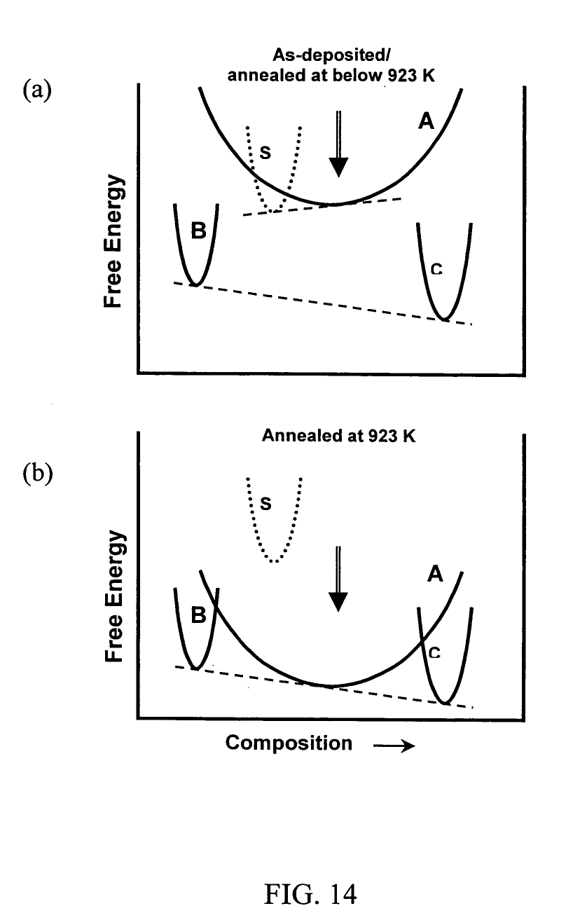

In this example, qualitatively, the thermal energy supplied by the annealing and the interfacial energy arising from the nanocrystalline/matrix interfaces have significant influences on the amorphization and crystallization of film during annealing. Upon annealing, our films clearly show a structure development sequence of metastable sputtered structure→metastable nanocrystallite/amorphous nanophase composite→single metastable amorphous phase→stable crystalline structure. To interpret the present results and explain the thermodynamics that govern the structure evolution during annealing, hypothetical free energy diagrams are shown in FIG. 14. The diagrams, though approximate, contain the essential features required to interpret the present results. The relative position of the free energy curves in the figure is rationalized based on thermodynamic considerations. In this figure, of primary importance is the large negative heat of mixing observed for the Fe-based alloy system. As stated in the previous section, has suggested that the large negative heat of mixing enables multicomponent alloys to readily form a glassy phase during cooling from the melt. The large negative heat of mixing and hence the low free energy of the amorphous phase can be related to the amorphization in our case. The low free energy provides the thermodynamic driving force for the amorphous phase to form as an intermediate phase during annealing, which eventually becomes thermodynamically stable by full crystallization at high temperatures.

In addition to the thermodynamic factor, the thermal energy at elevated temperatures and the interfacial energy arising from the nanocrystallite/glass interfaces are kinetically favorable for the amorphization, as proposed previously in SSA. At low temperatures, the large interfacial energy drives coarsening of the metastable crystalline phase through a process analogous to Ostwald ripening. Further, the viscosity of the glass matrix presumably decreases with temperature, analogous to that required for the superplasticity behavior of metallic glasses. The amorphous matrix, with a sufficiently low viscosity, allows the metastable nanocrystalline phases to “move around” and reorient in the matrix. An extensive amorphization occurs as the metastable nanocrystallites are thermally annihilated and “liquefied” into the amorphous matrix due to the combined effects of sufficient thermal energy and excessive interfacial energy. In contrast to the planar interfacial area in SSA multilayer films, the single layer films in this study are considered to yield much higher interfacial energies since nanocrystallite/amorphous matrix interfaces are present through the film thickness. As a result, wide spread amorphization could take place in the film. Above Tₓ, the amorphous structure is no longer thermodynamically favorable and crystallization readily proceeds.

### CONCLUSIONS

In this example, the Fe-based film shows the extensive amorphization phenomenon, presumably attributed to sufficient thermal and interfacial energies between nanocrystallites and amorphous matrix. The extensive amorphization gives rise to distinct variation in the electrical, mechanical and magnetic properties of annealed Fe-based film within supercooled liquid region. However, Fe-based film did not form fully amorphous structure as Zr-based film did. This might be due to the fact that Zr-based film has better glass-forming ability than Fe-based film. Some important results are summarized as follows.

(1) The electrical resistivity result indicates that Fe-based film has the high resistivity (˜228 μΩ-cm) within the supercooled liquid region.

(2) The Fe-based film has low ultra-microhardness (˜866.6 HK) with in the supercooled liquid region.

(3) TEM results show the Fe-based film has the amorphization taking place at 923 K.

(4) The VSM result shows the Fe-based film has low coercivity (˜33 Oe) and maximum saturated magnetization (˜0.027 emu/g) within the supercooled liquid region. Cyclic variation of coercivity and saturated magnetization with annealing temperature are observed.

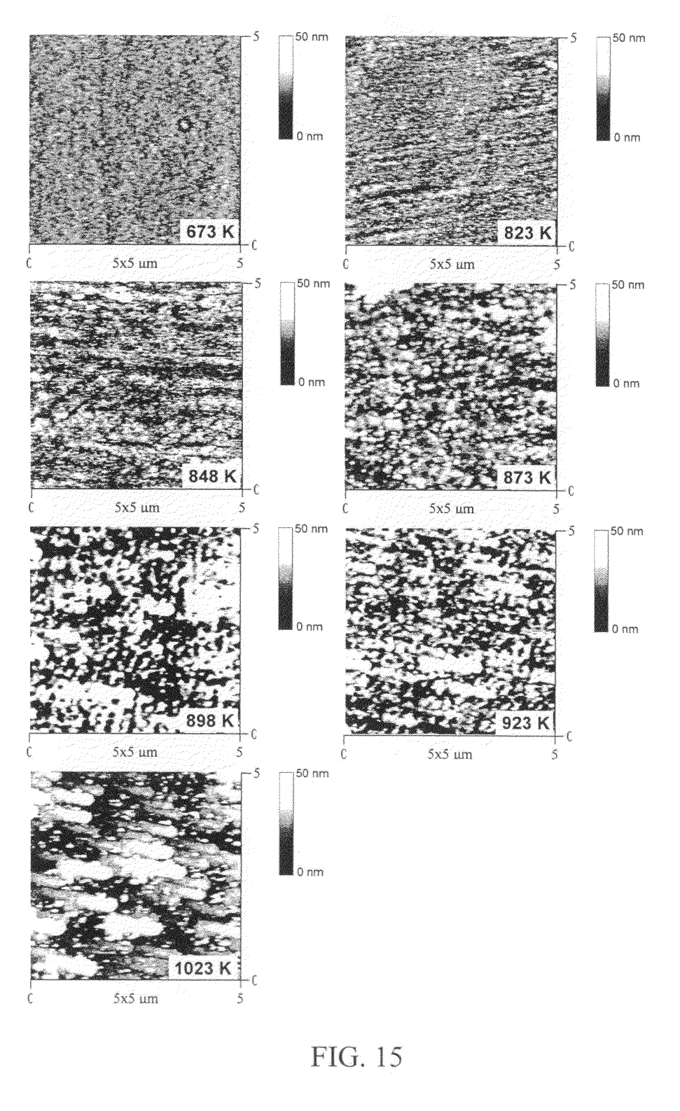

(5) The MFM result (FIG. 15) shows the domain structure of Fe-based film in agreement with electrical resistivity and TEM results.

### OTHER EMBODIMENTS

All of the features disclosed in this specification may be combined in any combination. Each feature disclosed in this specification may be replaced by an alternative feature serving the same, equivalent, or similar purpose. Thus, unless expressly stated otherwise, each feature disclosed is only an example of a generic series of equivalent or similar features.

From the above description, one skilled in the art can easily ascertain the essential characteristics of the present invention, and without departing from the spirit and scope thereof, can make various changes and modifications of the invention to adapt it to various usages and conditions. Thus, other embodiments are also within the scope of the following claims.

What is claimed is:

1. A process for manufacturing an alloy film comprising a principal element with high glass-forming ability and at least two secondary elements different from said principal element; said principal element with high glass-forming ability is selected from the group consisting of iron, cobalt, nickel, palladium, zirconium, titanium, magnesium, and lanthanide series; and said secondary elements are selected from the group consisting of aluminum, zirconium, copper, tin, zinc, palladium, titanium, iron, cobalt, nickel, niobium, beryllium, gallium, germanium, chromium, molybdenum, hafnium, lanthanide series, VI-VIII group transition elements, phosphorus, boron, carbon and silicon, comprising the following steps:
(a) using a alloy composed of the desired chemical elements as a film source;
(b) depositing the alloy onto a substrate to form a film; and
(c) annealing the film to induce partial or full amorphization in the film.

2. The process of claim 1, wherein the step of (b) is depositing the alloy onto a substrate to form a film by physical vapor deposition.

3. The process of claim 2, wherein said physical vapor deposition is DC or RR magnetron sputtering.

4. The process of claim 1, wherein the step of (c) is annealing the film by rapid thermal annealing to induce partial of full amorphization in the film.

5. The process of claim 1, wherein the step of (c) is annealing the film in an argon atmosphere.

6. The process of claim 1, wherein the heating rate of annealing in step (c) is 5 K/min˜200 K/min.

7. The process of claim 1, wherein the temperature of annealing in step (c) is in the supercooled liquid region of the alloy film.

8. The process of claim 1, wherein the temperature of annealing in step (c) is in the range of 400K˜1200K.

9. The process of claim 1, wherein the holding time of annealing in step (c) is 10 seconds˜3600 seconds.

10. The process of claim 1, wherein the step of (c) is annealing the film in an argon atmosphere, wherein the heating rate of annealing in step (c) is 5 K/min˜200K/min, the temperature of annealing in step (c) is in the range of 400K˜1200K and wherein the holding time of annealing in step (c) is 10 seconds˜3600 seconds.
